(19) United States
(12) Patent Application Publication
(10) Pub. No.: US 2024/0407246 A1
(43) Pub. Date: Dec. 5, 2024

(54) DISPLAY PANEL AND PREPARATION METHOD THEREFOR, AND DISPLAY DEVICE

(71) Applicants: Chongqing BOE Display Technology Co.,Ltd., Chongqing (CN); BOE Technology Group Co., Ltd., Beijing (CN)

(72) Inventors: Wei CHEN, Beijing (CN); Liang GAO, Beijing (CN); Hufei YANG, Beijing (CN); Ajuan DU, Beijing (CN); Xiaoxia HUANG, Beijing (CN); Yunhui HUANG, Beijing (CN); Hao SUN, Beijing (CN); Enjian YANG, Beijing (CN); Yilun ZENG, Beijing (CN); Yongle WANG, Beijing (CN); Yiqian WU, Beijing (CN); Guodong ZENG, Beijing (CN); Feifan LI, Beijing (CN)

(21) Appl. No.: 18/699,894

(22) PCT Filed: May 16, 2023
(86) PCT No.: PCT/CN2023/094522

§ 371 Date: Apr. 10, 2024

(30) Foreign Application Priority Data
May 23, 2022 (CN) 202210564884.8

(51) Int. Cl. H10K 77/10; H10K 59/12; H10K 59/80

(52) U.S. Cl. CPC H10K 77/111; H10K 59/1201; H10K 59/8794

(57) ABSTRACT

A display panel and a preparation method therefor, and a display device. The display panel comprises an active area and a peripheral area, which is arranged at the periphery of the active area and comprises a bending zone (410), wherein an edge of the peripheral area is provided with a protrusion (500), and the protrusion (500) has an alignment mark (400) for the bending zone (410).

### CROSS-REFERENCE TO RELATED APPLICATION

The present application is a U.S. National Phase Entry of International Application No. PCT/CN2023/094522 having an international filing date of May 16, 2023, which claims priority to Chinese Patent Application No. 202210564884.8, filed on May 23, 2022, to the China National Intellectual Property Administration, entitled “Display Panel and Preparation Method Therefor, and Display Device”. Contents of the above-identified applications should be regarded as being incorporated herein by reference.

### TECHNICAL FIELD

Embodiments of the present disclosure relate to, but not limited to, the field of display technologies, and in particular to a display substrate, a manufacturing method thereof and a display device.

### BACKGROUND

OLED (Organic Light Emitting Diodes) is widely used in the field of consumer electronics, especially in the mobile phone market. At present, pad bending technology is used in a bezel of display substrate. In order to improve the alignment accuracy of pad bending, an alignment mark is usually disposed on the display substrate, and positioning is realized by identifying the alignment mark.

Generally, the alignment mark is disposed between an edge of the display substrate and the display region. When a distance between the edge of the display substrate and the display region is very small, it is easy to cause the display region to have a greater exposure risk due to avoiding the alignment mark when manufacturing the related film layer later. In this way, mura defects are easy to occur in exposed site after illumination.

### SUMMARY

The following is a summary of subject matter described in detail in the present disclosure. This summary is not intended to limit the protection scope of claims.

An embodiment of the present disclosure provides a display substrate, including:
a display region; and
a peripheral region disposed at a periphery of the display region and including a bending region;
wherein, an edge of the peripheral region is provided with a protruding part, and the protruding part has an alignment mark for the bending region.

In some exemplary embodiments, a plane parallel to the display region is used as a reference plane, and an orthographic projection of the bending region on the reference plane is not overlapped with an orthographic projection of the protruding part on the reference plane.

In some exemplary embodiments, the display substrate further includes a curved region a plane parallel to the display region is used as a reference plane, and an orthographic projection of the curved region on the reference plane is not overlapped with an orthographic projection of the protruding part on the reference plane.

Alternatively, one end of a first region away from the bending region for disposing the protruding part has an arc chamfer, a plane parallel to the display region is used as a reference plane, and an orthographic projection of the arc chamfer on the reference plane is not overlapped with the orthographic projection of the protruding part on the reference plane.

In some exemplary embodiments, a distance between a side of the arc chamfer or the curved region close to the bending region and an edge of the bending region close to the protruding part is less than 3 mm, the protruding part is disposed at a side of the first region close to the bending region, and a third edge of the protruding part close to the bending region does not exceed a first edge of the bending region close to the first region.

In some exemplary embodiments, a distance between the arc chamfer and the bending region is greater than or equal to 3 mm, the protruding part is close to the arc chamfer, and a second edge of the protruding part away from the bending region does not exceed an edge of the arc chamfer close to the bending region.

In some exemplary embodiments, a distance between the curved region and the bending region is greater than or equal to 3 mm, and the protruding part is disposed at a side of the first region close to the curved region.

In some exemplary embodiments, a distance between an edge of the protruding part close to the curved region and an edge of the curved region close to the bending region is greater than or equal to 0.2 mm.

In some exemplary embodiments, a distance between a third edge of the protruding part close to the bending region and a first edge of the bending region close to the first region is greater than or equal to 1 mm.

In some exemplary embodiments, a plurality of thin film transistors are also included, the thin film transistors include a gate layer and a source-drain layer, and the alignment mark is disposed in the same layer as the gate layer or the source-drain layer.

In some exemplary embodiments, a protective layer disposed on an outer surface of the bending region is also included; in a direction of the peripheral region away from the display region, an edge of the protruding part away from the display region does not exceed a surface of the protective layer farthest away from the display region.

In some exemplary embodiments, a heat dissipation film is also included, the heat dissipation film is disposed facing away from a light emitting side of the display substrate; a plane parallel to the display region is used as a reference plane, and an orthographic projection of the heat dissipation film on the reference plane is overlapped with an orthographic projection of the display region on the reference plane.

In some exemplary embodiments, an edge of the peripheral region is also provided with a second protruding part, and the second protruding part has the same structure as the protruding part.

In some exemplary embodiments, a cover plate is also included, the cover plate is disposed at the light emitting side of the display substrate, and the cover plate is configured to fit a shape of one side of the display substrate and is adapted to the shape of the display substrate.

In some exemplary embodiments, the display substrate further includes:
an optical adhesive layer and a polarizer layer disposed between the cover plate and the light emitting side of the display substrate and stacked along the light emitting side of the display substrate;
a back film disposed between a backlight side of the display substrate and the heat dissipation film; and
a bending spacer layer disposed at a folded portion of the display substrate between the heat dissipation film and the back film.

An embodiment of the present disclosure further provides a display device which includes the display substrate according to any one of above embodiments.

An embodiment of the present disclosure further provides a manufacturing method of a display substrate, and the manufacturing method includes:
forming a display substrate, wherein the display substrate includes a display region and a peripheral region disposed at a periphery of the display region and including a bending region;
forming a protruding part at an edge of the peripheral region;
forming an alignment mark for the bending region on the protruding part.

In some exemplary embodiments, the method further includes: forming a heat dissipation film on the light emitting side facing away from the display substrate; a plane parallel to the display region is used as a reference plane, and an orthographic projection of the heat dissipation film on the reference plane is overlapped with an orthographic projection of the display region on the reference plane.

Other aspects of the present disclosure may be comprehended after the drawings and the detailed descriptions are read and understood.

### BRIEF DESCRIPTION OF DRAWINGS

FIG. 1A is a schematic diagram of a structure of an exemplary display substrate.

FIG. 1B is an enlarged view at A in FIG. 1A.

FIG. 2A is a rear view of an exemplary display substrate.

FIG. 2B is an enlarged view at A in FIG. 2A.

FIG. 2C is a cross-sectional view taken along CC′ direction in FIG. 2B.

FIG. 3 is a partial view of a lower bezel of an exemplary display substrate according to an embodiment of the present disclosure.

FIG. 4 is another partial view of a lower bezel of an exemplary display substrate according to an embodiment of the present disclosure.

FIG. 5 is a cross-sectional view taken along XX direction in FIG. 3.

FIG. 6A is a schematic diagram of a position of an exemplary alignment mark according to an embodiment of the present disclosure.

FIG. 6B is another schematic diagram of a position of an exemplary alignment mark according to an embodiment of the present disclosure.

FIG. 7 is a schematic diagram of a structure in which a surface of an exemplary display substrate according to an embodiment of the present disclosure is planar.

FIG. 8A is a schematic diagram of a position of an alignment mark when adopting an exemplary 2.5 D cover plate according to an embodiment of the present disclosure.

FIG. 8B is another schematic diagram of a positional relationship of an alignment mark when adopting an exemplary 2.5 D cover plate according to an embodiment of the present disclosure.

FIG. 8C is yet another schematic diagram of a positional relationship of an alignment mark when adopting an exemplary 2.5 D cover plate according to an embodiment of the present disclosure.

FIG. 9A shows a schematic diagram of a structure of an alignment mark according to an embodiment of the present disclosure.

FIG. 9B shows another schematic diagram of a structure of an alignment mark according to an embodiment of the present disclosure.

FIG. 10 is a flowchart of a manufacturing method of an exemplary display substrate according to an embodiment of the present disclosure.

FIG. 11A is a schematic diagram of a path of a first cutting for an exemplary protruding part according to an embodiment of the present disclosure.

FIG. 11B is a schematic diagram of a path of a second cutting for an exemplary protruding part according to an embodiment of the present disclosure.

### DETAILED DESCRIPTION

Specific implementation modes of the present disclosure will be described further in detail below with reference to the accompanying drawings and embodiments. The following embodiments are intended to illustrate the present disclosure and are exemplary only but are not intended to limit the scope of the present disclosure. The embodiments and features in the embodiments of the present disclosure may be randomly combined with each other if there is no conflict.

Unless otherwise defined, technical terms or scientific terms used in the embodiments of the present disclosure shall have common meanings understood by people with ordinary skills in the field to which the present disclosure pertains. “First”, “second”, and similar terms used in the embodiments of the present disclosure do not represent any order, quantity, or importance, but are only used for distinguishing different components. “Include”, “contain”, or similar words mean that elements or objects appearing before the words cover elements or objects and their equivalents listed after the words, but do not exclude other elements or objects. “Connect”, “couple”, or similar words are not limited to a physical or mechanical connection, but may include an electrical connection, whether direct or indirect. “Upper”, “lower”, “left”, and “right” and the like are used for representing a relative positional relationship, and when an absolute position of a described object is changed, the relative positional relationship may also be correspondingly changed.

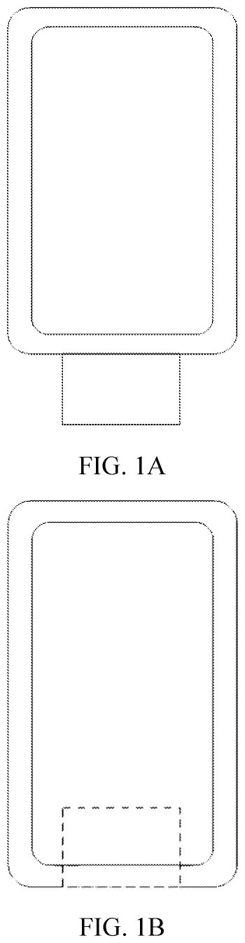

FIGS. 1A to 1B show front views of an exemplary display substrate before and after bending. FIG. 1A shows a schematic diagram of a structure of an exemplary display substrate before bending. FIG. 1B shows a schematic diagram of a structure of an exemplary display substrate of FIG. 1A after bending.

As shown in FIG. 1A, the display substrate may include upper, lower, left and right bezels, in which the lower bezel is the largest. In order to reduce the bezel(s) of the display substrate, a part of the lower bezel (for example, a part of a flexible circuit board) can be bent to a back surface of the display substrate by using a pad bending technique on the lower bezel of the display substrate, thus obtaining the structure shown in FIG. 1B.

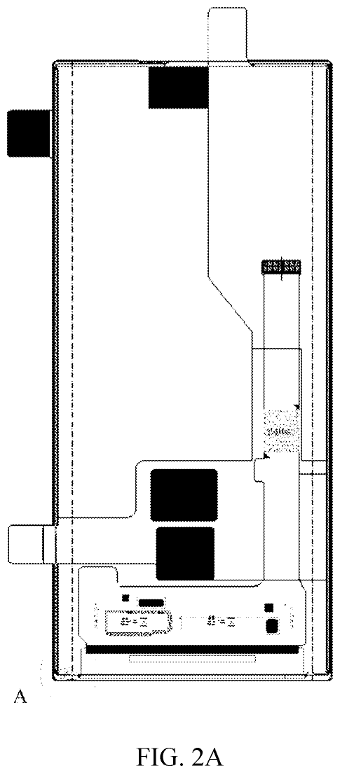

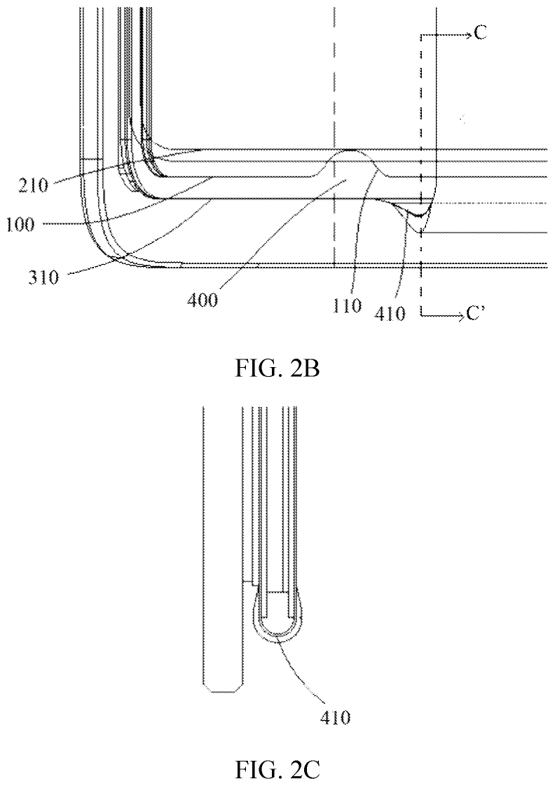

FIGS. 2A to 2C show rear views of another exemplary display substrate (after bending). FIG. 2A is a rear view of an exemplary display substrate. FIG. 2B is an enlarged view at A in FIG. 2A. FIG. 2C is a cross-sectional view taken along CC′ direction in FIG. 2B.

As shown in FIG. 2A, FIG. 2A is a schematic diagram of a structure of a back surface of the display substrate after a part of the lower bezel is bent to the back surface of the display substrate. Position A represents a local structure of the lower bezel, which is also a structure at a junction of the lower bezel and the left bezel. As shown in FIG. 2B, after position A is enlarged, a heat dissipation film layer is provided on a backlight side of the display substrate. The display substrate may include a display region (Active Area, AA) and a peripheral region. The peripheral region is disposed at a periphery of the display region. As shown in FIGS. 2B and 2C, a bending region 410 formed by bending the display substrate is also provided in the peripheral region. In order to improve the alignment accuracy of the bending region, an alignment mark 400 is usually provided at the peripheral region, and positioning is realized by identifying the alignment mark 400.

Some display substrates are provided with a heat dissipation film layer (SCF) on the back surface to guide heat generated during operation of the display substrate to the heat dissipation film layer. The heat dissipation film layer usually retracts inwardly compared with the display substrate and does not exceed an edge of the display substrate (panel). As shown in FIGS. 2B and 2C, a lower edge 100 of the heat dissipation film layer is generally located between a lower edge 210 of the display region and a lower edge 310 of the display substrate, and the alignment mark 400 is disposed between the lower edge 210 of the display region and the lower edge 100 of the heat dissipation film layer. Thus, it is necessary to provide a slot 110 in the heat dissipation film layer so as to expose the alignment mark 400 and facilitate positioning and identification. However, since a distance between the lower edge 210 of the display region and the lower edge 310 of the display substrate is small, an inner edge of the slot 110 of the lower edge 100 of the heat dissipation film layer is almost flush with the lower edge 210 of the display region. In the actual process, due to the tolerance of the shape of the slot 110 of the heat dissipation film layer and the tolerance of the bonding position of the heat dissipation film layer, the inner edge of the slot 110 of the heat dissipation film layer on the actually manufactured display substrate product will be located in the lower edge 210 of the display region, resulting in that the display region on the back surface of the display substrate cannot be completely covered. In this way, the brightness of the display region is easily uneven after being illuminated, and mura defects are easy to occur. Moreover, with the trend that the lower bezel design becomes narrower, the distance between the lower edge 210 of the display region and the lower edge 310 of the display substrate becomes smaller, and the risk of mura defects becomes greater.

An embodiment of the present disclosure provides a display substrate, which can solve, to a certain extent, the problem that the inner edge of the slot 110 of the heat dissipation film layer is located in the lower edge 210 of the display region, resulting in that the display region on the back surface of the display substrate cannot be completely covered and the mura is easy to occur after illumination.

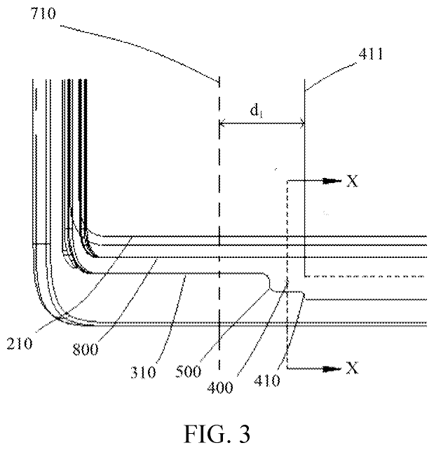

FIG. 3 shows a partial view of a lower bezel (e.g. a junction of the lower bezel and the left bezel) of an exemplary display substrate according to an embodiment of the present disclosure.

As shown in FIG. 3, the display substrate provided by the embodiment of the present disclosure may include: a display region and a peripheral region. The peripheral region may be disposed at the periphery of the display region and may include a bending region 410. An edge of the peripheral region, for example, an edge of the peripheral region away from the display region, i.e. a lower edge, is provided with a protruding part 500 having an alignment mark 400 of the bending region 410.

According to the display substrate provided by the embodiment of the present disclosure, by providing the protruding part 500 at the edge of the peripheral region (e.g. the edge away from the display region, i.e. the lower edge) and providing the alignment mark 400 on the protruding part 500, the alignment mark 400 can be provided in an area where the display substrate is not covered by other film layers (e.g. a heat dissipation film 800), that is, the alignment mark 400 does not need to be provided in an area where the display substrate is covered by other film layers (e.g., the heat dissipation film layer), thereby avoiding providing the slot 110 and the like on other film layers (e.g., the heat dissipation film layer), avoiding exposure of the display region under illumination, thereby reducing the risk of mura defects.

In some embodiments, a heat dissipation film 800 may be provided at a side of the display substrate facing away from a light emitting side. A plane parallel to the display region is used as a reference plane, and an orthographic projection of the heat dissipation film 800 on the reference plane is overlapped with an orthographic projection of the display region on the reference plane. In this way, the heat dissipation film can cover the display region, thus avoiding exposure of the display region under illumination and reducing the risk of mura defects.

In some embodiments, a plane parallel to the display region is used as a reference plane, and an orthographic projection of the bending region 410 on the reference plane is not overlapped with an orthographic projection of the protruding part 500 on the reference plane. That is, in the peripheral region, the bending region 410 and the protruding part 500 are discontinuous. In this way, the influence of the bending of the bending region 410 on the protruding part 500 can be avoided, and the protruding part 500 can be kept flat, so that the alignment mark 400 can be made as flat as possible, and the identification accuracy of the alignment mark 400 can be improved.

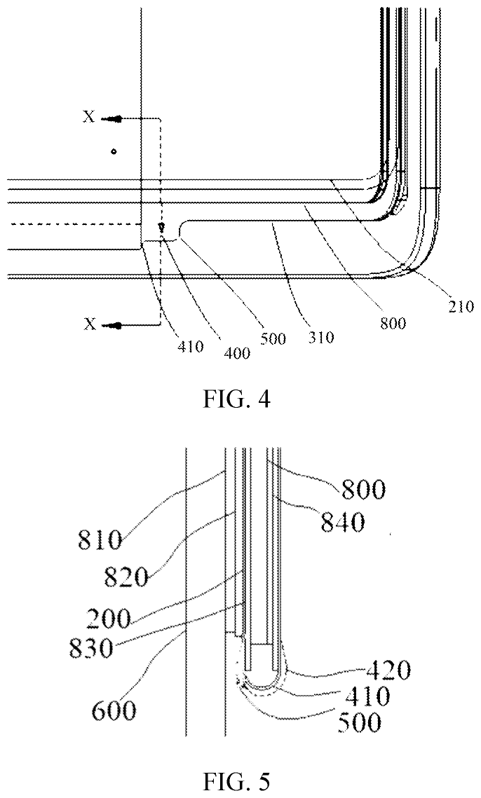

FIG. 4 shows a partial view of another lower bezel (e.g. a junction of the lower bezel and the right bezel) of an exemplary display substrate according to an embodiment of the present disclosure.

In some embodiments, as shown in FIG. 4, the protruding part 500 may also be provided in the peripheral region close to the right bezel of the display substrate. That is, two protruding parts 500 may be provided at the edge of the peripheral region. That is, in a width direction of the display substrate (i.e. in a direction from left to right), the protruding parts 500 may be provided on the left side (e.g. FIG. 3) and the right side (e.g. FIG. 4) of the lower bezel of the display substrate. In this way, by providing the protruding parts 500 at both sides of the bending region 410, the positioning can be better realized by the alignment marks 400 at both sides of the bending region 410, the bending deviation can be minimized, the uniformity of the overall stress distribution of the bending region 410 can be improved, and problems such as fracture of the inorganic layer of the bending region 410 caused by uneven stress can be avoided.

In an exemplary embodiment, the structures of the protruding parts 500 provided on the left side (e.g. FIG. 3) and the right side (e.g. FIG. 4) of the lower bezel of the display substrate are the same, and in order to avoid repeated description, the protruding part 500 at the left side of the lower bezel of the display substrate will be described below.

FIG. 5 shows a cross-sectional view taken along XX direction in FIG. 3.

In some embodiments, with reference to FIG. 5, a cover plate 600 may also be included. The cover plate 600 may be disposed at the light emitting side of the display substrate 200. The cover plate 600 is used for fitting a shape of one side of the display substrate and is adapted to the shape of the display substrate 200. For example, if the display substrate has a planar structure, the cover plate 600 may be a 2.5D cover plate. If the display substrate is a curved screen, for example, the edge of the display substrate is curved in a direction away from the light emitting side, the cover plate 600 may be a 3D cover plate. An optical adhesive (OCA) layer 810 and a polarizer (POL) layer 820 stacked along the light emitting side of the display substrate may also be included between the cover plate 600 and the light emitting side of the display substrate. A back film (BF) 830 may also be included between the backlight side of the display substrate and the heat dissipation film 800. A bending spacer layer 840 may also be provided between the heat dissipation film 800 and the back film at a portion where the display substrate is folded.

Returning to FIG. 3, the display substrate can be a curved screen. In the display substrate with this structure, after the display substrate is bent, a curved region (for example, the curved region can be used for display), a first region, and a bending region 410 may be included along a width direction of the display substrate. The curved region is connected to the first region, and there is a virtual boundary line 710 between the curved region and the first region. The first region is connected to the bending region 410, and a virtual boundary line between the first region and the bending region 410 may be a first edge 411 of the display substrate after bending. That is, the curved region is connected to a side of the first region away from the bending region 410. In an exemplary embodiment, the first region may be an area from the virtual boundary line 710 between the curved region and the first region to the first edge 411 of the bending region 410 after the display substrate is bent. The protruding part 500 may be disposed in the first region, so that the protruding part 500 may be kept as flat as possible, thereby facilitating good identification of the alignment mark 400. The protruding part 500 may be disposed at a side of the first region close to the bending region 410 or at a side of the first region close to the curved region. In an exemplary embodiment, a body region of the cover plate 600 for fitting the curved screen may include a cover plate curved region and a cover plate first region. A virtual boundary line between the cover plate curved region and the cover plate first region, i.e. the bending position of the 3D cover plate, substantially coincides with the virtual boundary line 710 between the curved region and the first region of the display substrate.

In some embodiments, when the space of the first region is insufficient, for example, when the distance d₁ between the curved region (or the virtual boundary line 710 between the curved region and the first region) and the bending region 410 (or the first edge 411 of the bending region 410 close to the first region, i.e. the left edge) is less than 3 mm, the protruding part 500 may be disposed at a side of the first region close to the bending region 410. In this way, the protruding part 500 can be kept as far away from the curved region as possible, and the protruding part 500 can be kept as flat as possible, so that the alignment mark 400 can be made as flat as possible, thereby facilitating good identification of the alignment mark 400 and improving the identification accuracy of the alignment mark 400. In this way, it is possible to avoid inaccurate identification caused by disposing the alignment mark 400 in the curved region.

In some embodiments, the protruding part 500 may be as close as possible to the side of the first region close to the bending region 410, as long as the edge of the protruding part 500 close to the bending region does not exceed the boundary line between the first region and the bending region 410 (or the first edge 411 of the bending region 410 close to the first region, i.e. the left edge). For example, an edge of the protruding part 500 close to the bending region 410 may be disposed at the first edge 411. In an exemplary embodiment, the edge of the protruding part 500 close to the bending region and the first edge 411 of the bending region 410 close to the first region may be partially approximately coincided and be discontinuous. In an exemplary embodiment, as shown in FIG. 3, with a plane parallel to the display region as a reference plane, an orthographic projection of the edge of the protruding part 500 close to the bending region on the reference plane is not overlapped with an orthographic projection of the first edge 411 of the bending region 410 on the reference plane. The protruding part 500 is kept flat, thereby making the alignment mark 400 as flat as possible and improving the identification accuracy of the alignment mark 400.

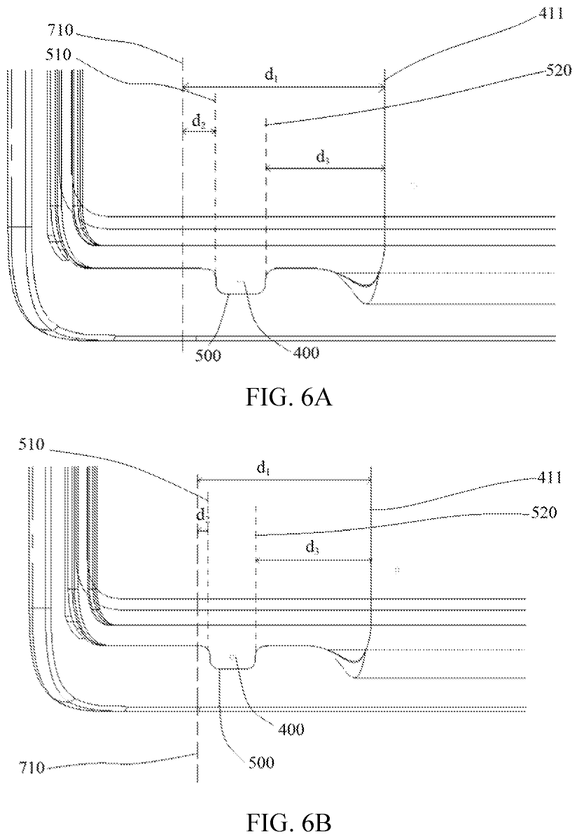

FIGS. 6A to 6B show schematic diagrams of positions of exemplary alignment marks 400 according to embodiments of the present disclosure. FIG. 6A is a schematic diagram of a position of an exemplary alignment mark 400 according to an embodiment of the present disclosure. FIG. 6B is another schematic diagram of a position of an exemplary alignment mark 400 according to an embodiment of the present disclosure.

In some embodiments, as shown in FIGS. 6A and 6B, when the space of the first region is sufficient, for example, when a distance d₁ between the curved region (or the virtual boundary line 710 between the curved region and the first region) and the bending region 410 (or the first edge 411 of the bending region 410 close to the first region) is greater than or equal to 3 mm, the protruding part 500 may be disposed at a side of the first region close to the curved region. In this way, the process can be simplified, and the protruding part 500 can be formed only by one cutting.

In some embodiments, as shown in FIG. 6A, a distance d₂ between an edge of the protruding part 500 close to the curved region (i.e., a second edge 510 of the protruding part away from the bending region 410) and the virtual boundary line 710 (i.e., the bending position of the 3D cover plate) may be greater than 0.2 mm. Alternatively, as shown in FIG. 6B, the distance d₂ between the edge of the protruding part 500 close to the curved region (i.e., the second edge 510 of the protruding part away from the bending region 410) and the virtual boundary line 710 (i.e., the bending position of the 3D cover plate) may be equal to 0.2 mm. That is, a minimum distance between the protruding part 500 and the curved region is 0.2 mm or more. This prevents the protruding part 500 from entering the curved region of the 3D cover plate when the display substrate is attached to the 3D cover at the extreme position, prevents the alignment mark 400 from being not accurately recognized due to the bending of the curved region, and improves the identification accuracy of the alignment mark 400.

In some embodiments, a distance d₃ between the edge of the protruding part 500 away from the curved region, i.e. a third edge 520 of the protruding part close to the bending region 410, and the first edge 411 may be 1 mm. Alternatively, the distance d₃ between the edge of the protruding part 500 away from the curved region (i.e. the third edge 520 of the protruding part close to the bending region 410) and the first edge 411 may be greater than 1 mm. That is, a minimum distance between the protruding part 500 and the bending region 410 is 1 mm or more. Thus, it is possible to avoid burning a part of the first edge 411 when cutting the protruding part 500 during the manufacturing of the protruding part 500 (e.g. laser cutting manufacturing).

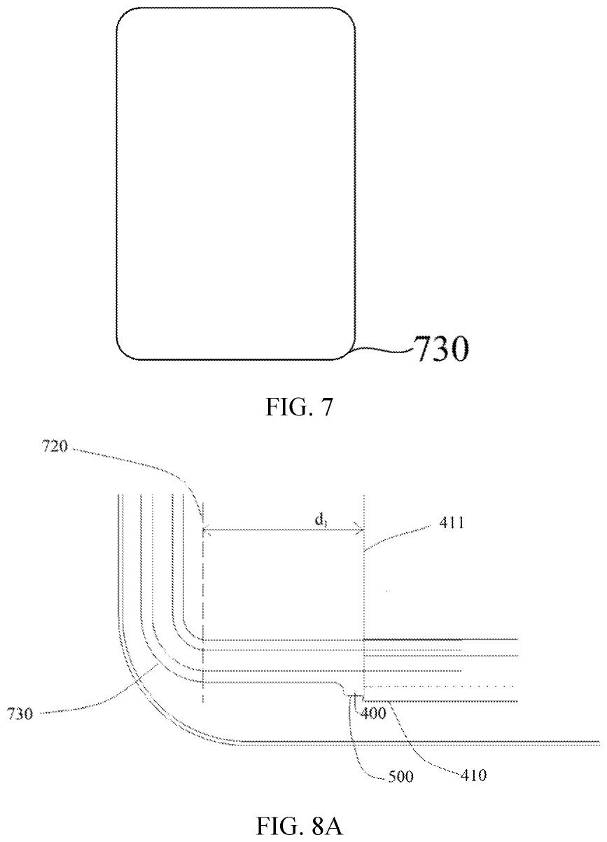

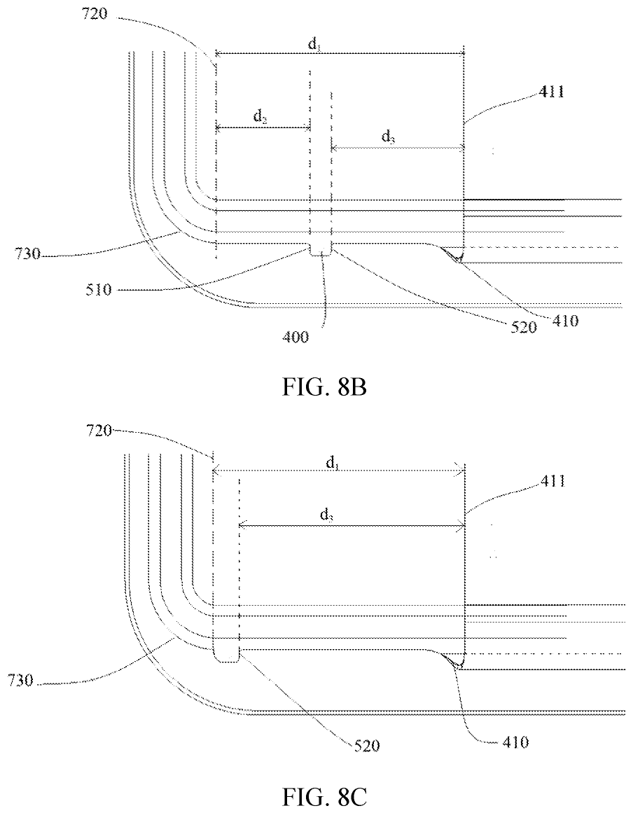

FIG. 7 shows a schematic diagram of a structure in which a surface of an exemplary display substrate according to an embodiment of the present disclosure is planar. FIGS. 8A to 8C show another schematic diagrams of structures of exemplary alignment marks 400 according to embodiments of the present disclosure. FIG. 8A is a schematic diagram of a position of an alignment mark 400 when adopting an exemplary 2.5 D cover plate according to an embodiment of the present disclosure. FIG. 8B is another schematic diagram of a positional relationship of an alignment mark 400 when adopting an exemplary 2.5 D cover plate according to an embodiment of the present disclosure. FIG. 8C is yet another schematic diagram of a positional relationship of an alignment mark 400 when adopting an exemplary 2.5 D cover plate according to an embodiment of the present disclosure.

Referring to FIG. 7, the surface of the display substrate may be planar. For example, the shape of the display substrate may be rectangular. The corners of the display substrate may be chamfered, such as an arc chamfer 730. Referring to FIGS. 8A to 8C, in the display substrate with this structure, the peripheral region may include a first region connected to the bending region 410, and a boundary line between the first region and the bending region 410 may be a first edge 411 of the bending region 410 close to the first region, for example, the left edge. An end of the first region away from the bending region 410 has an arc chamfer 730. In an exemplary embodiment, the first region may be an area from the left edge of the display substrate to the first edge 411 of the bending region 410. The protruding part 500 may be disposed in the first region, so that the protruding part 500 may be kept as flat as possible, thereby facilitating good identification of the alignment mark 400. The protruding part 500 may be disposed at a side of the first region close to the bending region 410 or at a side of the first region close to the arc chamfer 730. In an exemplary embodiment, a body region of the cover plate 600 for the display substrate may be planar and have a cover plate arc chamfer. A boundary of the cover plate arc chamfer is almost not at the same position as the boundary of the arc chamfer 730 of the display substrate.

In some embodiments, as shown in FIG. 8A, when space in the first region is insufficient, for example, when the distance d₁ between the arc chamfer 730 (or a virtual edge 720 of the arc chamfer 730 close to the bending region) and the bending region 410 (or the first edge 411 of the bending region 410 close to the first region) is less than 3 mm, the protruding part 500 may be disposed at a side of the first region close to the bending region 410. In this way, the protruding part 500 can be kept as far away from the arc chamfer 730 as possible, and the alignment mark 400 can be kept as flat as possible, so that the alignment mark 400 can be kept as flat as possible, thereby facilitating good identification of the alignment mark 400 and improving the identification accuracy of the alignment mark 400. In this way it is possible to avoid the inability to accurately identify the alignment mark 400 caused by disposing the alignment mark 400 at the arc chamfer 730.

In some embodiments, the protruding part 500 may be as close as possible to the side of the first region close to the bending region 410, as long as a third edge 520 of the protruding part 500 close to the bending region does not exceed the boundary line between the first region and the bending region 410 (the first edge 411 of the bending region 410 close to the first region). For example, the third edge 520 of the protruding part 500 close to the bending region 410 may be disposed at the first edge 411. In an exemplary embodiment, the third edge 520 of the protruding part 500 close to the bending region 410 and the first edge 411 of the bending region 410 close to the first region may be partially approximately coincided and be discontinuous. In an exemplary embodiment, as shown in FIG. 8A, with a plane parallel to the display region as a reference plane, an orthographic projection of the third edge 520 of the protruding part 500 close to the bending region on the reference plane is not overlapped with an orthographic projection of the first edge 411 of the bending region 410 on the reference plane, so that the protruding part 500 is kept flat, thereby making the alignment mark 400 as flat as possible and improving the identification accuracy of the alignment mark 400.

In some embodiments, as shown in FIGS. 8B and 8C, when space in the first region is sufficient, for example, when the distance between the arc chamfer 730 (or the virtual edge 720 of the arc chamfer 730 close to the bending region) and the bending region 410 (or the first edge 411 of the bending region 410 close to the first region) is greater than or equal to 3 mm, the protruding part 500 may be disposed at a side of the first region close to the arc chamfer 730. In this way, the process can be simplified, and the protruding part 500 can be formed by only one cutting.

In some embodiments, the protruding part 500 may be disposed as close to the arc chamfer 730 as possible, as long as the edge of the protruding part 500 close to the arc chamfer 730 (i.e., the second edge 510 of the protruding part 500 away from the bending region 410) does not exceed the virtual edge 720 of the arc chamfer 730 (i.e., the edge of the arc chamfer 730 close to the bending region 410). For example, as shown in FIG. 8C, the edge of the protruding part 500 close to the arc chamfer 730, i.e. the second edge 510 of the protruding part away from the bending region, may coincide with the virtual edge 720.

In some embodiments, as shown in FIGS. 8B and 8C, the distance d₃ between the edge of the protruding part 500 away from the arc chamfer 730, i.e. the third edge 520 of the protruding part close to the bending region, and the first edge 411 may be more than 1 mm, i.e. greater than or equal to 1 mm. Thus, it is possible to avoid burning a part of the first edge 411 when cutting the protruding part 500 during the manufacturing of the protruding part 500 (e.g. laser cutting manufacturing).

In some embodiments, returning to FIG. 5, a protective layer 420 may also be provided on an outer surface of the bending region 410, i.e. the surface at a side of the bending region 410 opposite to a bending direction of the bending region 410. The protective layer 420 is mainly used for supporting and protecting the surface of the bending region 410. The protective layer 420 may be an MCL (Micro Coating Layer) adhesive layer. The edge of the protruding part 500 away from the display region may not exceed a surface of the MCL adhesive layer farthest away from the display region. In this way, the influence of the protruding part 500 being disposed at the edge of the peripheral region on assembly can be reduced as much as possible, so that assembly is facilitated, and wear and the like on the protruding part 500 during assembly can be avoided.

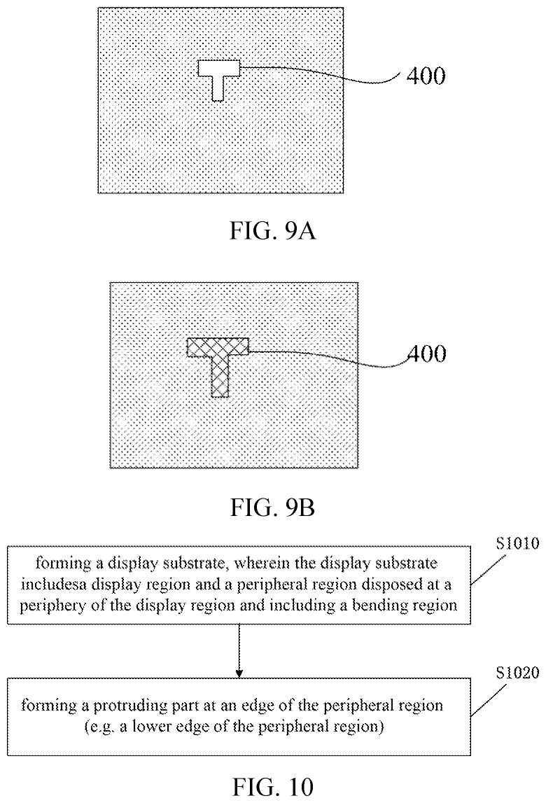

FIG. 9A shows a schematic diagram of a structure of an alignment mark 400 according to an embodiment of the present disclosure.

In some embodiments, the display substrate may include a thin film transistor. The thin film transistor may include a gate layer and a source-drain layer. A light-transmissible alignment mark 400 may be formed by directly forming a hollow region on the gate layer or the source-drain layer. At this time, in the gate layer or the source-drain layer, since the light transmittance at the alignment mark 400 is higher than other regions, the alignment mark 400 can be identified on both the light emitting side and the backlight side of the display substrate, so that the alignment mark 400 can be accurately identified. That is, the alignment mark 400 may be disposed in internal stacked layers of the display substrate.

FIG. 9B shows another schematic diagram of a structure of an alignment mark 400 according to an embodiment of the present disclosure.

In some embodiments, the material of the alignment mark 400 may be a metal having a shape, so that the alignment mark 400 may be disposed in the same layer as the gate layer or the source-drain layer. For example, the gate layer or the source-drain layer is exposed, etched, developed, etc. to form the alignment mark 400, which simplifies the manufacturing process of the alignment mark 400.

In some embodiments, with a plane parallel to the display region as a reference plane, an orthographic projection of the alignment mark 400 on the reference plane may be a common shape, such as a T-shape or a cross shape, as long as it is easy to identify.

In the display substrate provided by the embodiment of the present disclosure, by disposing the protruding part 500 at the edge of the peripheral region of the display substrate away from the display region, and disposing the alignment mark 400 at the protruding part 500, the position where the alignment mark 400 is disposed is not overlapped with the position where the heat dissipation film 800 is attached to the display substrate, and there is no need to provide a slot on the heat dissipation film 800 to avoid the alignment mark 400. In this way, the inner edge of the slot of the heat dissipation film 800 is prevented from being located in the lower edge 210 of the display region, thereby avoiding mura defects caused by the inability to completely cover the display region.

An embodiment of the present disclosure further provides a display device. The display device includes the display substrate as described in any of the above embodiments.

The display device of the above-described embodiment has the display substrate of any of the above-described embodiments and has the corresponding beneficial effects of the display substrate embodiments, which will not be repeated here.

An embodiment of the present disclosure also provides a manufacturing method of a display substrate, which is used for manufacturing the display substrate in any of the above embodiments.

FIG. 10 shows a flowchart of a manufacturing method of an exemplary display substrate according to an embodiment of the present disclosure. The method may include the following steps.

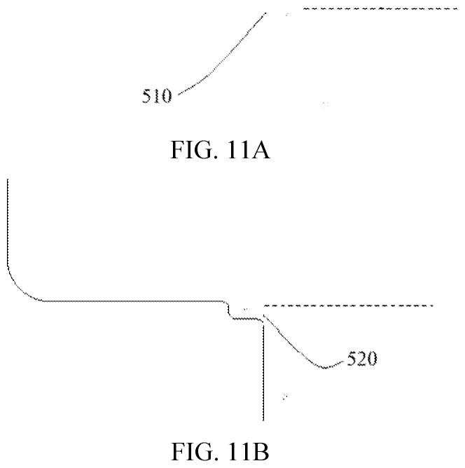

Step S1010: forming a display substrate. The display substrate includes a display region and a peripheral region disposed at a periphery of the display region and including a bending region 410; Step S1020: forming a protruding part 500 at an edge of the peripheral region (e.g. a lower edge 210 of the peripheral region). In some embodiments, the protruding part may be formed by cutting in manner of laser. For example, FIGS. 11A to 11B show a cutting process of an exemplary protruding part 500 provided by an embodiment of the present disclosure. FIG. 11A is a path of a first cutting (e.g. laser cutting) and FIG. 11B is a path of a second cutting (e.g. laser cutting).

In some embodiments, when the protruding part 500 is disposed at a side of a first region (e.g. in FIG. 3, the area from the virtual boundary line 710 between the curved region and the first region to the first edge 411 of the bending region 410) close to the bending region 410, for example, referring to FIG. 11A, a partial structure of the protruding part 500 (e.g. the structure in FIG. 3 that does not include the third edge 520 of the protruding part 500 close to the bending region) may be first formed by performing cutting at the bending region of the display substrate. That is, the display substrate is cut for the first time to form the protruding part and the bending region before the display substrate is bent which are adjacent. Then, referring to FIG. 11B, a third edge 520 of the protruding part 500 close to the bending region is formed at a side of the protruding part 500 close to the bending region by cutting, so that the protruding part 500 and the bending region 410 are disconnected and discontinuous, thereby forming the protruding part 500 of FIG. 3 or FIG. 8A. That is, cutting at the side of the protruding part close to the bending region is performed, so that an orthographic projection of the protruding part on a reference plane are not overlapped with an orthographic projection of the bending region on the reference plane, the reference plane being a plane parallel to the display region. In this way, a display substrate before bending the bending region is formed. In this way, the influence of the bending of the bending region 410 on the protruding part 500 can be avoided, and the protruding part 500 can be kept flat, so that the alignment mark 400 can be made as flat as possible, and the identification accuracy of the alignment mark 400 can be improved.

In other embodiments, when the protruding part 500 is disposed at a side of the first region away from the bending region 410, the protruding part 500 may be formed by cutting directly at the lower edge 310 of the display substrate at one time. For example, the protruding part 500 is formed by directly cutting at the lower edge 310 of the display substrate to obtain the protruding part 500 shown in FIG. 6A, 6B, 8A, 8B, or 8C. In this way, the protruding part 500 can be formed by one cutting, and the protruding part 500 can be kept flat, thereby making the alignment mark 400 as flat as possible and improving the identification accuracy of the alignment mark 400.

In step S1030, the alignment mark 400 of the bending region 410 is formed in the protruding part 500.

In some embodiments, the display substrate may include a thin film transistor. The thin film transistor may include a gate layer and a source-drain layer. The light-transmissible alignment mark 400 may be formed by directly forming a hollow region on the gate layer or the source-drain layer (e.g. as shown in FIG. 9A). At this time, the principle of the alignment mark may be that, in the gate layer or the source-drain layer, since the light transmittance at the alignment mark 400 is higher than other regions, the alignment mark 400 can be identified on both the light emitting side and the backlight side of the display substrate, so that the alignment mark 400 can be accurately identified. That is, the alignment mark 400 may be disposed in internal stacked layers of the display substrate.

In some embodiments, the material of the alignment mark 400 may be a metal having a shape, so that the alignment mark 400 may be disposed in the same layer as the gate layer or the source-drain layer. For example, the gate layer or the source-drain layer is exposed, etched, developed, etc. to form the alignment mark 400 (e.g. as shown in FIG. 9B), which simplifies the manufacturing process of the alignment mark 400.

In some embodiments, the manufacturing process further includes affixing the heat dissipation film 800 at a side (i.e. the backlight side) of the display substrate facing away from the light emitting side. With a plane parallel to the display region as a reference plane, an orthographic projection of the heat dissipation film 800 on the reference plane is overlapped with an orthographic projection of the display region on the reference plane. In this way, the heat dissipation film layer does not need to have a slot structure or the like to avoid the alignment mark 400, thereby avoiding exposure of the display region and reducing the risk of mura defects.

Those skilled in the art should understand that the discussion in any of the above embodiments is only exemplary and is not intended to imply that the scope of the present disclosure (including the claims) is limited to these examples. Under the concept of the present disclosure, the above embodiments or the technical features in different embodiments may be combined, and the steps may be implemented in any order. There are many other changes in different aspects of the embodiments of the present disclosure as described above, which are not provided in details for simplicity.

In addition, well-known power/ground connections to integrated circuit (IC) chips and other components may or may not be shown in the provided drawings. Moreover, an apparatus may be illustrated in a form of a block diagram in order to avoid obscuring the embodiments of the present disclosure, which also considers the fact that details about implementation modes of apparatuses in these block diagrams highly depend on a platform on which the embodiments of the present disclosure will be implemented, that is, these details should be fully within a understanding range of those skilled in the art. In the case where specific details (for example, circuits) are set forth to describe exemplary embodiments of the present disclosure, it would be apparent to those skilled in the art that the embodiments of the present disclosure may be implemented without these specific details or with changes in these specific details. Therefore, these descriptions should be considered illustrative rather than restrictive.

Although the present disclosure is described in combination with specific embodiments of the present disclosure, many replacements, modifications, and variations of these embodiments are apparent to those skilled in the art according to the previous description.

The embodiments of the present disclosure are intended to cover all such replacements, modifications, and variations that fall within the broad scope of the appended claims. Therefore, any omissions, modifications, equivalent replacements, improvements and the like made within the spirit and principle of the embodiments of the present disclosure shall be included within the scope of protection of the present disclosure.

1. A display substrate, comprising:
a display region; and
a peripheral region disposed at a periphery of the display region and comprising a bending region;
wherein, an edge of the peripheral region is provided with a protruding part, and the protruding part has an alignment mark for the bending region.

2. The display substrate according to claim 1, wherein a plane parallel to the display region is used as a reference plane, and an orthographic projection of the bending region on the reference plane is not overlapped with an orthographic projection of the protruding part on the reference plane.

3. The display substrate according to claim 1, wherein,
when the display substrate is a curved screen, the display substrate further comprises a curved region, a plane parallel to the display region is used as a reference plane, an orthographic projection of the curved region on the reference plane is not overlapped with an orthographic projection of the protruding part on the reference plane; or
when a surface of the display substrate is planar, one end of a first region away from the bending region for disposing the protruding part in the display substrate has an arc chamfer, a plane parallel to the display region is used as a reference plane, and an orthographic projection of the arc chamfer on the reference plane is not overlapped with an orthographic projection of the protruding part on the reference plane.

4. The display substrate according to claim 3, wherein a distance between a side of the arc chamfer or the curved region close to the bending region and an edge of the bending region close to the protruding part is less than 3 mm, the protruding part is disposed at a side of the first region close to the bending region, and a third edge of the protruding part close to the bending region does not exceed a first edge of the bending region close to the first region.

5. The display substrate according to claim 3, wherein a distance between the arc chamfer and the bending region is greater than or equal to 3 mm, the protruding part is close to the arc chamfer, and a second edge of the protruding part away from the bending region does not exceed an edge of the arc chamfer close to the bending region.

6. The display substrate according to claim 3, wherein a distance between the curved region and the bending region is greater than or equal to 3 mm, and the protruding part is disposed at a side of the first region close to the curved region.

7. The display substrate according to claim 6, wherein a distance between an edge of the protruding part close to the curved region and an edge of the curved region close to the bending region is greater than or equal to 0.2 mm.

8. The display substrate according to claim 5, wherein a distance between a third edge of the protruding part close to the bending region and a first edge of the bending region close to the first region is greater than or equal to 1 mm.

9. The display substrate according to claim 1, further comprising a plurality of thin film transistors, wherein the thin film transistors comprise a gate layer and a source-drain layer, and the alignment mark is disposed in the same layer as the gate layer or the source-drain layer.

10. The display substrate according to claim 1, further comprising a protective layer disposed on an outer surface of the bending region; wherein in a direction of the peripheral region away from the display region, an edge of the protruding part away from the display region does not exceed a surface of the protective layer farthest away from the display region.

11. The display substrate according to claim 1, further comprising a heat dissipation film disposed facing away from a light emitting side of the display substrate;
a plane parallel to the display region is used as a reference plane, and an orthographic projection of the heat dissipation film on the reference plane is at least partially overlapped with an orthographic projection of the display region on the reference plane.

12. The display substrate according to claim 1, wherein an edge of the peripheral region is further provided with a second protruding part, and the second protruding part has the same structure as the protruding part.

13. The display substrate according to claim 11, further comprising a cover plate disposed on the light emitting side of the display substrate, wherein the cover plate is configured to fit a shape of one side of the display substrate and is adapted to the shape of the display substrate.

14. The display substrate according to claim 13, further comprising:
an optical adhesive layer and a polarizer layer disposed between the cover plate and the light emitting side of the display substrate and stacked along the light emitting side of the display substrate;
a back film disposed between a backlight side of the display substrate and the heat dissipation film; and
a bending spacer layer disposed at a folded portion of the display substrate between the heat dissipation film and the back film.

15. A display device, comprising: the display substrate according to claim 1.

16. A manufacturing method of a display substrate, comprising:
forming a display substrate, wherein the display substrate comprises a display region and a peripheral region disposed at a periphery of the display region and comprising a bending region;
forming a protruding part at an edge of the peripheral region;
forming an alignment mark for the bending region on the protruding part.

17. The manufacturing method of a display substrate according to claim 16, wherein forming a protruding part at an edge of the peripheral region comprises:
cutting the display substrate to form the protruding part and the bending region before the display substrate is bent which are adjacent;
cutting on a side of the protruding part close to the bending region so that an orthographic projection of the protruding part on a reference plane is not overlapped with an orthographic projection of the bending region on the reference plane; wherein the reference plane is a plane parallel to the display region.

18. The display substrate according to claim 6, wherein a distance between a third edge of the protruding part close to the bending region and a first edge of the bending region close to the first region is greater than or equal to 1 mm.

19. The display substrate according to claim 7, wherein a distance between a third edge of the protruding part close to the bending region and a first edge of the bending region close to the first region is greater than or equal to 1 mm.

20. A display device, comprising: the display substrate according to claim 2.
